(19) United States
(12) Patent Application Publication
(10) Pub. No.: US 2014/0319524 A1
(43) Pub. Date: Oct. 30, 2014

(54) SUBSTRATES HAVING A BROADBAND ANTIREFLECTION LAYER AND METHODS OF FORMING A BROADBAND ANTIREFLECTION LAYER

(71) Applicant: University of Florida Research Foundation, Inc., Gainesville, FL (US)

(72) Inventors: Blayne Michael Phillips, Gainesville, FL (US); Peng Jiang, Gainesville, GA (US)

(21) Appl. No.: 14/363,127

(22) PCT Filed: Dec. 7, 2012
(86) PCT No.: PCT/US2012/068390

§ 371 Date: Jun. 5, 2014

Related U.S. Application Data
(60) Provisional application No. 61/568,685, filed on Dec. 9, 2011.

(51) Int. Cl. H01L 31/0232; H01L 33/58; H01L 31/18; G02B 1/11; H01L 33/00

(52) U.S. Cl. CPC H01L 31/02327; G02B 1/11; H01L 33/0054; H01L 31/182; H01L 33/58
USPC 257/49; 438/29; 438/72

(57) ABSTRACT

In accordance with the purpose(s) of the present disclosure, as embodied and broadly described herein, embodiments of the present disclosure, in one aspect, relate to methods of making substrates having an antireflective layer, substrates having an antireflective layer, devices including a substrate having an antireflective layer, and the like.

### CLAIM OF PRIORITY TO RELATED APPLICATION

This application claims priority to co-pending U.S. provisional application entitled “SUBSTRATES HAVING A BROADBAND ANTIREFLECTION LAYER AND METHODS OF FORMING A BROADBAND ANTIREFLECTION LAYER” having Ser. No. 61/568,685, filed on Dec. 9, 2011, which is entirely incorporated herein by reference.

### BACKGROUND

Photovoltaics (PVs) produce electric power via conversion of the planet's most abundant and renewable energy input: sunlight. Crystalline silicon solar cells are among the most mature and efficient photovoltaic technology; in addition, silicon is the second most abundant element in the earth's crust. The production of photovoltaic panels is dominated by crystalline silicon solar cells with 98% of the market share. More specifically, 36% of the 2004 production is based on single crystal silicon, 58% on multi-crystalline silicon, and 4% on thin film amorphous silicon. Ideally, a solar cell should absorb all useful photons. However, due to the high refractive index of silicon, more than 35% of incident light is reflected back from the surface of crystalline silicon. Antireflection coatings (ARCs) are therefore widely utilized to reduce reflective losses and improve conversion efficiencies of silicon PVs. Thus, there is a need to address and/or overcome these deficiencies.

### SUMMARY

In accordance with the purpose(s) of the present disclosure, as embodied and broadly described herein, embodiments of the present disclosure, in one aspect, relate to methods of making substrates having an antireflective layer, substrates having an antireflective layer, devices including a substrate having an antireflective layer, and the like.

In an embodiment, a method of forming an antireflective layer on a substrate, among others, includes: disposing a multi-cyrstalline silicon substrate in a solution; disposing the particles in the solution so that the particles cover the surface of the solution, wherein the particles are silica particles having a diameter of about 500 nm or less; removing the substrate from the solution so that the particles form a colloidal monolayer of particles on the surface of the substrate; etching the substrate having the colloidal monolayer of particles disposed thereon to form the an antireflective layer on the substrate, wherein the antireflective layer has a height of about 500 nm to 1000 nm, wherein the anti reflective layer has a plurality of pillars that have a spacing of about 10 nm to 300 nm between a pair of pillars as measured from pillar base to pillar base, and the pillar has a diameter at the base of about 50 to 300 nm; and removing the colloidal monolayer of particles.

In an embodiment, a structure, among others, includes: a multi-crystalline silicon substrate having an antireflective layer that has a total specular reflection of less than 10%, wherein the antireflective layer has a height of about 500 nm to 1000 nm, wherein the antireflective layer has a plurality of pillars that have a spacing of about 10 nm to 300 nm between a pair of pillars as measured from pillar base to pillar base, and wherein the pillar has a diameter at the base of about 50 to 300 nm.

In an embodiment, a method of forming an antireflective layer on a substrate, among others, includes: forming a colloidal monolayer of particles on a surface of a substrate; and etching the substrate having the colloidal monolayer of particles disposed thereon to form the an antireflective layer on the substrate.

In an embodiment, a structure, among others, includes: a multi-crystalline silicon substrate having an antireflective layer that has a total specular reflection of less than 10%.

Other systems, methods, features, and advantages will be, or become, apparent to one with skill in the art upon examination of the following drawings and detailed description. It is intended that all such additional structures, systems, methods, features, and advantages be included within this description, be within the scope of the present disclosure, and be protected by the accompanying claims.

### BRIEF DESCRIPTION OF THE DRAWINGS

Many aspects of this disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1.1 illustrates a scanning electron microscopy image of the surface of a multicrystalline silicon wafer.

FIG. 1.2 illustrates a photograph of a commercial solar-grade multicrystalline silicon wafer coated with silica particles by LB method.

FIG. 1.3 shows the scanning electron microscopy image of the surface of the wafer covered in silica particles.

FIG. 1.4 is a magnified image of the same sample, where the hexagonal ordering of monolayer silica particles is clearly seen from these electron microscopy images.

FIG. 1.5 shows the wafer after RIE etching, the dark part of the wafer is the area that was exposed to the plasma and the top light part was shielded from the plasma.

FIG. 1.6 shows a top view scanning electron microscopy image of the etched sample though it is difficult to see the pillar structure from this view.

FIG. 1.7 shows a tilted view of scanning electron microscopy image of the RIE-etched multicrystalline silicon wafer where the subwavelength-structured pillars can clearly be seen.

FIG. 1.8 illustrates a comparison of total specular reflection obtained from a RIE-etched multicrystalline silicon wafer, an untreated commercial multicrystalline silicon wafer, and a polished flat single-crystalline silicon wafer.

FIGS. 2.1(a) and (b) shows the SEM image of a hexagonally close packed array of the silicon on the surface.

FIG. 2.2 shows a 45 degree tilted SEM image that shows the generated features formed on a 100 crystal oriented wafer. FIG. 2.2(a) shows the etch using 100 nm particles, FIG. 2.2(b) shows the etch using 200 nm particles, FIG. 2.2(c) shows the etch using 250 nm particles, and FIG. 2.2(d) shows the etch using 300 nm particles.

FIG. 2.3(a) shows the features generated on 111 crystal oriented silicon. FIG. 2.3(b) shows the etch using 200 nm particles, FIG. 2.3(c) shows the etch using 250 nm particles, and FIG. 2.3(d) shows the etch using 300 nm particles.

FIG. 2.4 illustrates the optical properties of 100 textured wafer.

FIG. 2.5 illustrates the optical properties of 111 textured wafer.

FIG. 2.6 shows a 4 inch wafer that has been textured using this process.

### DETAILED DESCRIPTION

This disclosure is not limited to particular embodiments described, and as such may, of course, vary. The terminology used herein serves the purpose of describing particular embodiments only, and is not intended to be limiting, since the scope of the present disclosure will be limited only by the appended claims.

Where a range of values is provided, each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Embodiments of the present disclosure will employ, unless otherwise indicated, techniques of chemistry, material science, and the like, which are within the skill of the art. Such techniques are explained fully in the literature.

The following examples are put forth so as to provide those of ordinary skill in the art with a complete disclosure and description of how to perform the methods and use the structures disclosed and claimed herein. Efforts have been made to ensure accuracy with respect to numbers (e.g., amounts, temperature, etc.), but some errors and deviations should be accounted for. Unless indicated otherwise, parts are parts by weight, temperature is in ° C., and pressure is at or near atmospheric. Standard temperature and pressure are defined as 20° C. and 1 atmosphere.

Before the embodiments of the present disclosure are described in detail, it is to be understood that, unless otherwise indicated, the present disclosure is not limited to particular materials, reagents, reaction materials, manufacturing processes, dimensions, frequency ranges, applications, or the like, as such can vary. It is also to be understood that the terminology used herein is for purposes of describing particular embodiments only, and is not intended to be limiting. It is also possible in the present disclosure that steps can be executed in different sequence, where this is logically possible. It is also possible that the embodiments of the present disclosure can be applied to additional embodiments involving measurements beyond the examples described herein, which are not intended to be limiting. It is furthermore possible that the embodiments of the present disclosure can be combined or integrated with other measurement techniques beyond the examples described herein, which are not intended to be limiting.

It should be noted that, as used in the specification and the appended claims, the singular forms “a,” “an,” and “the” include plural referents unless the context clearly dictates otherwise. Thus, for example, reference to “a support” includes a plurality of supports. In this specification and in the claims that follow, reference will be made to a number of terms that shall be defined to have the following meanings unless a contrary intention is apparent.

Each of the applications and patents cited in this text, as well as each document or reference cited in each of the applications and patents (including during the prosecution of each issued patent; “application cited documents”), and each of the PCT and foreign applications or patents corresponding to and/or claiming priority from any of these applications and patents, and each of the documents cited or referenced in each of the application cited documents, are hereby expressly incorporated herein by reference. Further, documents or references cited in this text, in a Reference List before the claims, or in the text itself; and each of these documents or references (“herein cited references”), as well as each document or reference cited in each of the herein-cited references (including any manufacturer's specifications, instructions, etc.) are hereby expressly incorporated herein by reference.

Prior to describing the various embodiments, the following definitions are provided and should be used unless otherwise indicated.

### Discussion

Embodiments of the present disclosure provide for methods of making substrates having an antireflective layer, substrates having an antireflective layer, devices including a substrate having an antireflective layer, and the like. Embodiments of the substrate are advantageous over other substrates due to the high thermal, radiation stability, and/or lifetime of the antireflective layer of the substrates. Embodiments of the substrate can be used in solar cells, thermophotovoltaic cells, organic light emitting diodes (OLEDs), and semiconductor light emitting diodes.

In an embodiment, the antireflective layer is formed from the substrate, which enhances the mechanical and environmental stability of the substrate and antireflective coating. In an embodiment, the antireflective layer can have a total specular reflection that is much less than other substrates (e.g., a total specular reflection less than about 10% for a multi-crystalline silicon substrate). Since the substrates have such a low total spectral reflection, devices including the substrates do not need sun-tracking mechanisms.

In an embodiment, the structure of the antireflective layer can increase the water contact angle so that the substrates can be self-cleaning. Additional details are described in the Examples section.

In an embodiment, the method of making the antireflective layer is easier, faster, and/or less expensive than other techniques for making similar structures. In an exemplary embodiment, the method of forming an antireflective layer on a substrate includes forming (e.g., self-assembled) a colloidal monolayer of particles (e.g., silica) on the surface of a substrate. Next, the substrate is etched to form the antireflective layer on the substrate. Subsequently, the colloidal monolayer of particles on the surface can be removed.

In an exemplary embodiment, the colloidal monolayer of particles can be formed on the substrate by disposing the particles in a first solution (e.g., water) so that the particles cover the surface of the first solution. In an embodiment, the particles can be put into a second solution (e.g., ethylene glycol) and then disposed into the first solution. In an embodiment, the second solution causes the particles to disperse evenly across the surface of the first solution via colloidal self-assembly.

Once the particles are disposed on the surface of the first solution, the substrate can be removed from the first solution so that the particles form a colloidal monolayer of particles on the surface of the substrate. In an embodiment, the particles can be disposed on the substrate as an ordered colloidal monolayer (e.g., a hexagonal ordering). The substrate can be disposed in the first solution prior to the addition of the particles to the first solution or the substrate can be disposed in the first solution after the addition of the particles to the first solution.

In an embodiment, the first solution can be water, ethanol, butanol, or a mixture thereof. In an embodiment, the second solution can be ethylene glycol, toluene, benzene, or a mixture thereof. In an embodiment, the first solution is water and the second solution is ethylene glycol.

After the particles are disposed on the surface of the substrate, the substrate can be etched to form the antireflective layer on the substrate. In an exemplary embodiment, the etching can include a reactive ion etching process. The particles are selected so that they are etched at a slower rate or are not etched at all relative to the substrate. In other words, the exposed areas of the substrate are etched and the areas under the particles are not etched. The etching process forms the antireflective layer. The conditions (e.g., temperature, chemical reactants, pressure, etc.) of the etching process can be adjusted to modify the physical characteristics (e.g., thickness of the anti reflective layer, one or more dimensions of the pillars that form the antireflective layer, and the like) of the antireflective layer. Additional details regarding the etching process are described in the Examples.

After the substrate is etched, the particles can be removed from the surface of the substrate. In an embodiment, the particles can be removed using an acid (e.g., HF) treatment. Other methods that can be used include ultrasonication, scratching, or a combination thereof.

In an exemplary embodiment, the substrate can include a silicon substrate, a gallium arsenide (GaAs) substrate, a gallium antimonide (GaSb) substrate, indium phosphide (InP), gallium nitride (GaN), and the like. In an embodiment, the silicon substrate can include a single crystal silicon substrate, a multi-crystalline substrate, or an amorphous silicon substrate. In an embodiment, the substrate can have a thickness of about 2 μm to 1000 μm and the length and width can vary depending upon the desired use or application.

In an exemplary embodiment, the substrate can be processed to form the antireflective layer. In an embodiment, the antireflective layer can be referred to as a moth-eye grating. In an embodiment, the antireflective layer has a total specular reflection of about 10% or less, about 8%, or less, about 5% or less, about 3% or less, or about 1% or less, for the entire visible wavelength at an incident angle of about 0° to 180°. In a particular exemplary embodiment, the substrate is a multi-crystalline silicon substrate and the antireflective layer has a total specular reflection of about 10% or less, about 8%, or less, about 5% or less, about 3% or less, or about 1% or less. The phrase “total specular reflection” means the overall specular reflection obtained from a substrate surface with reflection angle between 0 and 180 degrees. An integration sphere can be used in measuring total specular reflection.

In an exemplary embodiment, the antireflective layer has a height (or depth of the etched structure) of about 500 nm to 2000 nm or about 500 nm to 1000 nm. In an embodiment, the removal of the substrate below the particles form pillars made of the substrate material. In an embodiment, the pillars can have a spacing of about 10 nm to 300 nm between a pair of pillars as measured from the pillar base to pillar base, where the spacing can vary between multiple pairs of pillars.

In an embodiment, the pillar can have a diameter at the base of about 50 to 300 nm or about 50 to 150 nm. The pillar may have the same or different diameter along the length of the pillar. In an embodiment, the pillar tapers from the base to the top of the pillar, where the diameter of the pillar at the midpoint of the length of the pillar can be about 50 nm to 300 nm or about 50 to 150 nm.

In an embodiment, the pillar can have a length or height of about 100 to 2000 nm or about 100 nm to 1000 nm. In an embodiment, the length of the pillars can vary depending on the surface morphology of the substrate so that some pillars are much longer than others. For example, the length of the pillars can vary significantly in a multi-crystalline silicon substrate due to the surface morphology. Thus, the length of each of the pillars in the antireflective layer can vary widely.

In an exemplary embodiment, the particles can have a size of about 1 to 500 nm along its longest dimension. In particular, if the particle is spherical in shape, the diameter can be about 1 to 500 nm or about 100 to 300 nm. In an embodiment, the particle can be made of a material that etches at a slower rate or is not etched during the etching process employed to form the antireflective layer. In particular, the particle can be made of a material such as silica, polystyrene, titania, alumina, and a combination thereof. In a particular embodiment, the substrate is a silicon substrate (e.g., a multi-crystalline substrate) and the particle is made of silica.

While embodiments of the present disclosure are described in connection with the Example and the corresponding text and figures, there is no intent to limit the disclosure to the embodiments in these descriptions. On the contrary, the intent is to cover all alternatives, modifications, and equivalents included within the spirit and scope of embodiments of the present disclosure.

### EXAMPLE 1

Photovoltaics (PVs) produce electric power via conversion of the planet's most abundant and renewable energy input: sunlight. Crystalline silicon solar cells are among the most mature and efficient photovoltaic technology; in addition, silicon is the second most abundant element in the earth's crust. The production of photovoltaic panels is dominated by crystalline silicon solar cells with 98% of the market share. More specifically, 36% of the 2004 production is based on single crystal silicon, 58% on multi-crystalline silicon, and 4% on thin film amorphous silicon. Ideally, a solar cell should absorb all useful photons. However, due to the high refractive index of silicon, more than 35% of incident light is reflected back from the surface of crystalline silicon. Antireflection coatings (ARCs) are therefore widely utilized to reduce reflective losses and improve conversion efficiencies of silicon PVs.

Quarter-wavelength silicon nitride (SiNₓ) films deposited by plasma enhanced chemical vapor deposition (PECVD) are the industrial standard for ARCs on crystalline silicon substrates. Unfortunately, the PECVD-deposited SiNₓ films are expensive to fabricate due to the high cost of chemical precursors and of processing in vacuum chambers. Additionally, commercial SiNₓ ARCs can only suppress reflection efficiently at wavelengths around 600 nm. The reflective loss is rapidly increased for near-infrared and other visible wavelengths, which contain a large portion of the incident solar energy. Moreover, traditional quarter-wavelength ARCs exhibit low thermal stability because of the mismatch of the thermal expansion coefficient between the substrate and the coatings, limiting the efficiency of photovoltaics working at extreme conditions (e.g., outer space and concentrating PVs). By contrast, subwavelength-structured moth-eye ARCs directly patterned in the substrates are broadband and intrinsically more stable and durable than multilayer ARCs since no foreign material is involved. Nevertheless, current top-down lithographic technologies in creating subwavelength silicon gratings, such as electron-beam lithography, nanoimprint lithography, and interference lithography, require sophisticated equipment and are expensive to implement. To lower manufacturing cost and increase conversion efficiency of photovoltaics, it is highly desirable to develop inexpensive nanofabrication techniques that enable large-scale production of broadband and thermally stable ARCs for reducing reflection over a broad range of wavelengths and angles of incidence.

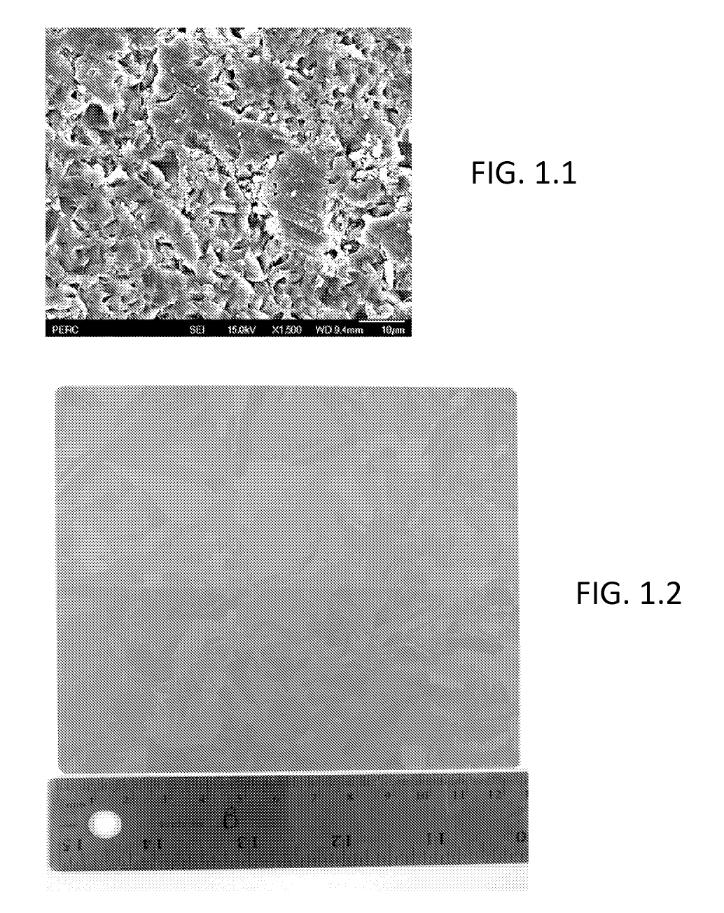

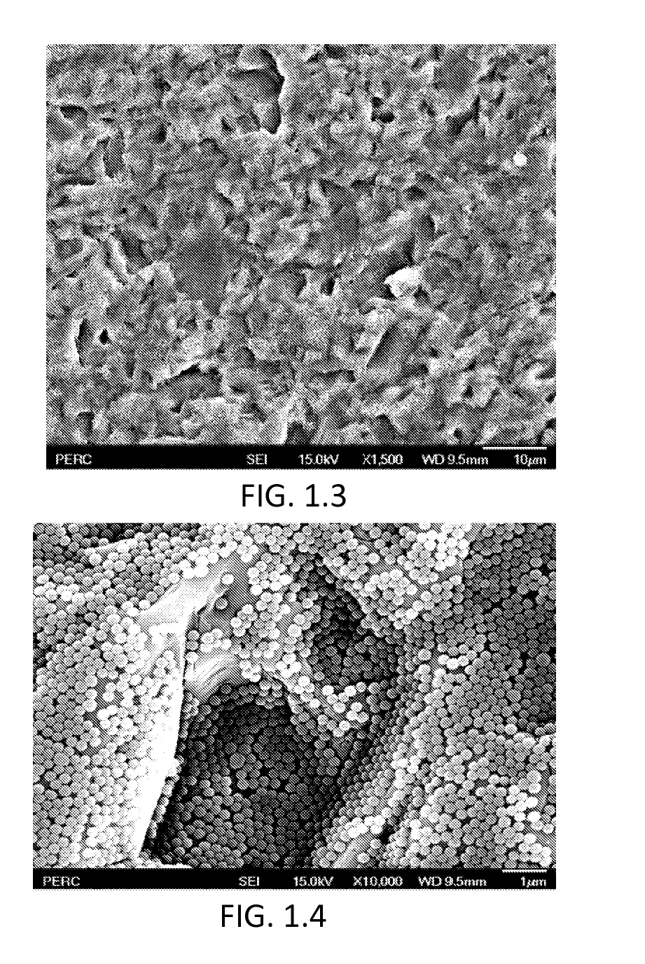

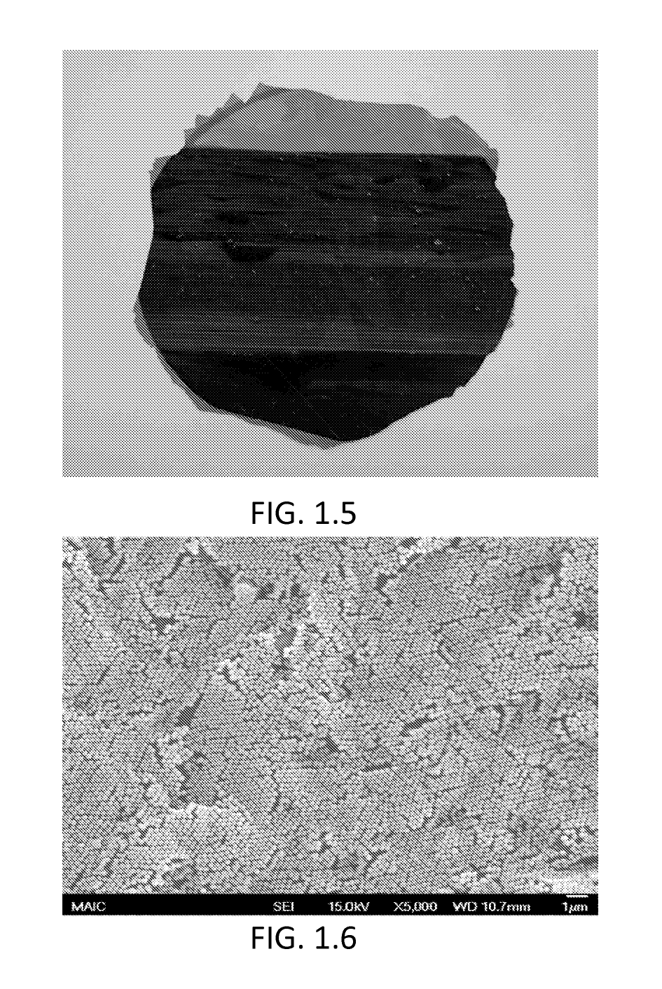

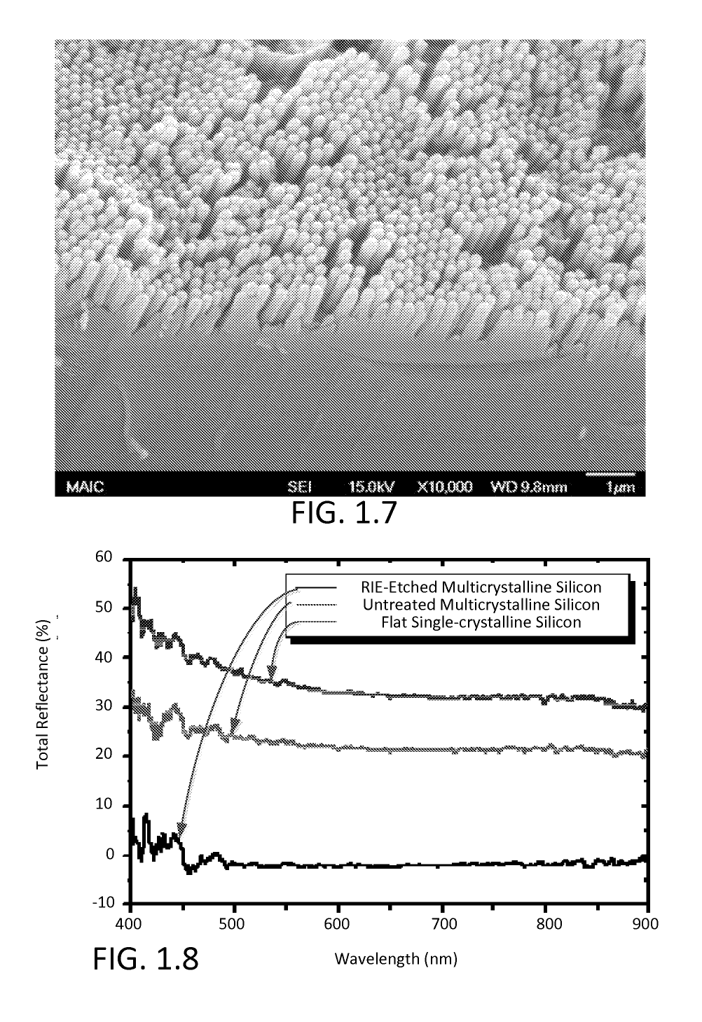

The disclosed technology is based on colloidal self-assembly and templating nanofabrication to create wafer-scale broadband antireflection coatings on solar grade multicrystalline silicon wafers. The principle of the method is to first assemble colloidal silica monolayers on multicrystalline silicon wafers. The assembled silica particles can then be used as etching masks in a subsequent reactive ion etching (RIE) process to transfer the hexagonal pattern of the particles into the multicrystalline silicon substrates. Silica particles are etched much slower than silicon during RIE and they can therefore protect the silicon substrate underneath them from being etched. This will create moth-eye gratings directly in multicrystalline silicon. The silica particles can finally be removed by a brief wet etching in hydrofluoric acid aqueous solution. One big challenge of this approach is the rough surface of commercial multicrystalline silicon substrates (see FIG. 1.1). The high roughness prevents the formation of ordered colloidal monolayers on the wafer surface. FIG. 1.1 illustrates a scanning electron microscopy image of the surface of a multicrystalline silicon wafer.

To revolve the surface roughness issue, we developed a Langmuir-Blodgett (LB) method to enable the formation of ordered colloidal silica monolayers on the rough multicrystalline silicon wafers. Silica particles with diameter ranging from 100 to 300 nm, which are dispersed in ethylene glycol, are added drop wise to the surface of water contained in a large glass beaker. The particles can be seen floating on the surface of the water. They form crystalline structures on the surface of the water that can be observed due to the brilliant colors caused by Bragg diffraction of visible light. Once the entire surface is covered with silica particles it is left for 10 minutes for the silica particles on the surface to form a homogeneous layer on the surface of the water. A multicrystalline silicon wafer is then slowly withdrawn from the beaker at a rate of about 0.5 mm/min. As the wafer is withdrawn it is coated with a monolayer of silica particles.

A photograph of a commercial solar-grade multicrystalline silicon wafer coated with silica particles by LB method is shown in FIG. 1.2. The top half of the image is the uncoated wafer and the bottom half is the coated wafer. It is apparent that the silica coating is quite uniform over the whole coated area. The LB method can be easily applied to coat a whole wafer in a continuous manner. FIG. 1.3 shows the scanning electron microscopy image of the surface of the wafer covered in silica particles. FIG. 1.4 is a magnified image of the same sample. The hexagonal ordering of monolayer silica particles is clearly seen from these electron microscopy images.

The coated wafer is then dry etched using an Unaxis RIE/ICP reactive ion etcher with chlorine gas. The etching is performed at a pressure of 5 mTorr with a gas flow of 20 SCCM operating at a plasma power of 80 W for differing amounts of time. The final step of this method is to soak the wafer in a 2% HF solution to remove the remaining silica particles. FIG. 1.5 shows the wafer after RIE etching, the dark part of the wafer is the area that was exposed to the plasma; the top light blue part was shielded from the plasma. The wafer here is cut to be circular to fit inside of the RIE chamber in UF NRF which requires samples to have a maximum diameter of 4 inches. There are many types of commercial reactive ion etchers that can easily process solar grade multicrystalline silicon wafers. FIG. 1.6 shows a top view scanning electron microscopy image of the etched sample though it is difficult to see the pillar structure from this view. FIG. 1.7 shows a tilted view of scanning electron microscopy image of the RIE-etched multicrystalline silicon wafer where the subwavelength-structured pillars can clearly be seen.

The total specular reflectance from a polished single-crystalline silicon wafer, a commercial solar-grade multicrystalline silicon wafer, and the RIE-etched multicrystalline silicon wafer is compared in FIG. 1.8. Specifically, FIG. 1.8 illustrates a comparison of total specular reflection obtained from a RIE-etched multicrystalline silicon wafer, an untreated commercial multicrystalline silicon wafer, and a polished flat single-crystalline silicon wafer. The polished single-crystalline silicon wafer shows >30% total reflection for visible and near-IR wavelengths. The untreated multicrystalline silicon wafer exhibits a lower total reflection due to the rough surface structure though the total reflection is still above 20%. The subwavelength-structured multicrystalline silicon wafer shows close to zero total reflection. This indicates that almost all light from any incident angle will be absorbed by the patterned multicrystalline silicon substrate, promising for improving the conversion efficiency of multicrystalline silicon solar cells.

### EXAMPLE 2

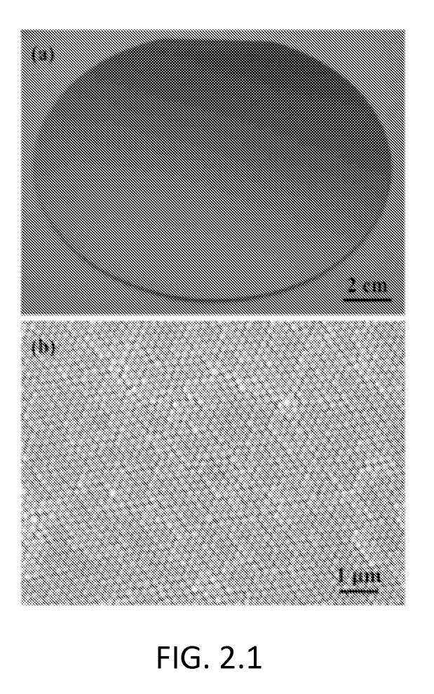

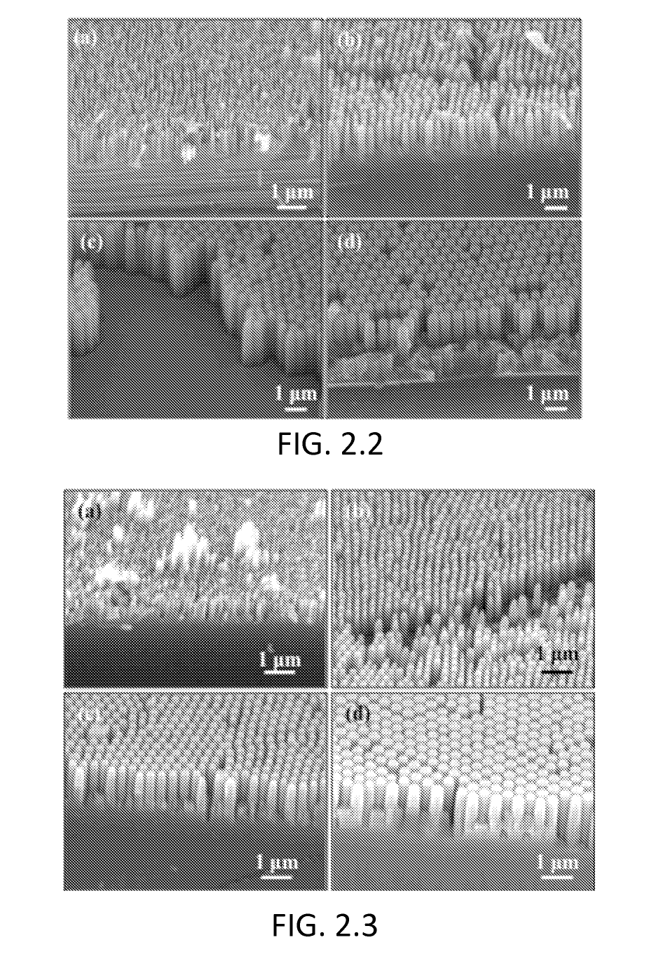

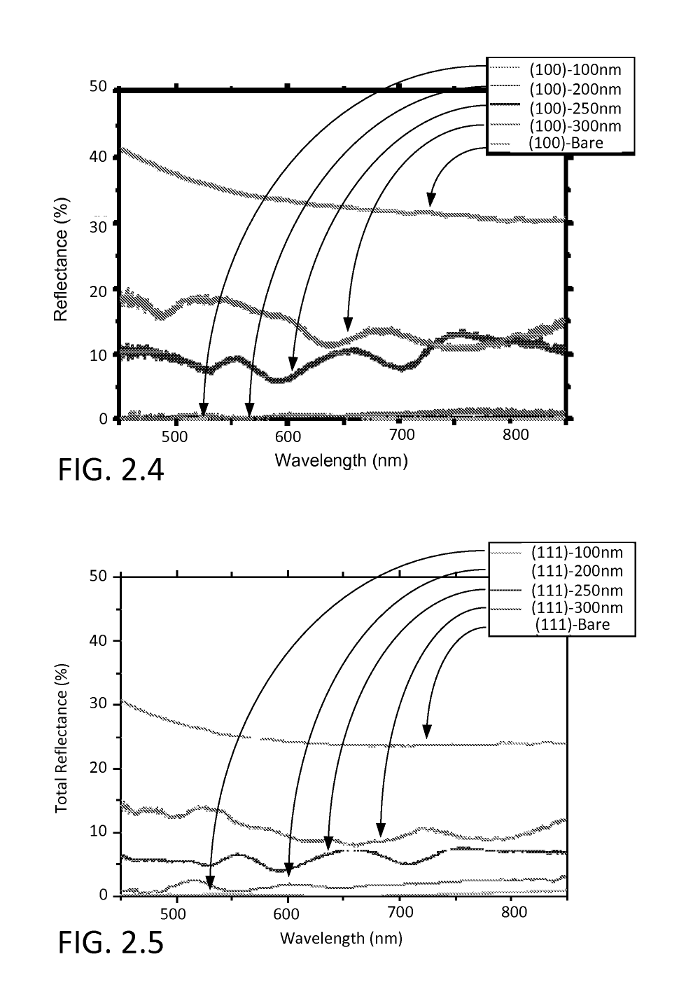

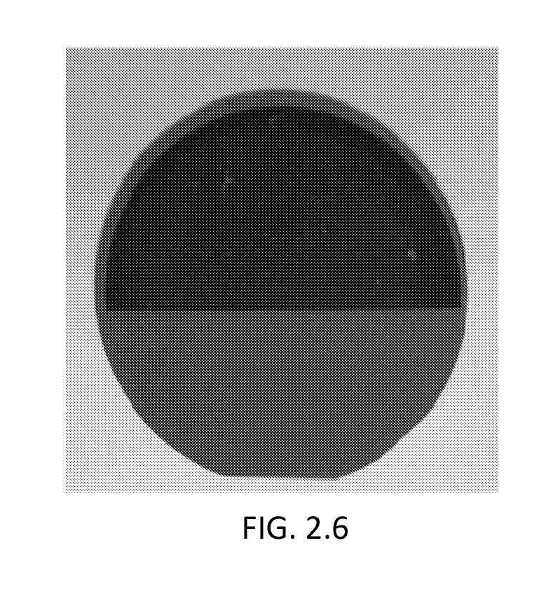

The Langmuir-Blodgett coating process was used to coat 100 and 111 crystal oriented wafers with 100 nm, 200 nm, 250 nm, and 300 nm particles. Using the developed process full-scale coverage of a 6 inch diameter silicon wafer is demonstrated see FIG. 2.1(a). The uniform greenish-blue color shown is the color of the coating over the grey silicon. The SEM image in FIG. 2.1 (b) shows the hexagonally close packed arrays of the silicon on the surface.

Chlorine reactive ion etch followed was used to generate the moth-eye pillar array on the surface of the wafer. A dilute HF etch was then used to remove any remaining SiO₂ from the surface of the wafer. FIG. 2.2 shows a 45 degree tilted SEM image that shows the generated features formed on a 100 crystal oriented wafer. FIG. 2.2(a) shows the etch using 100 nm particles, FIG. 2.2(b) shows the etch using 200 nm particles, FIG. 2.2(c) shows the etch using 250 nm particles, and FIG. 2.2(d) shows the etch using 300 nm particles.

FIG. 2.3 shows the features generated on 111 crystal oriented silicon. FIG. 2.3(b) shows the etch using 200 nm particles, FIG. 2.3(c) shows the etch using 250 nm particles, and FIG. 2.3(d) shows the etch using 300 nm particles.

Visually the texturing on the different orientations of silicon is indistinguishable. This demonstrates the flexibility of this process in that it can be used on multicrystalline substrates or substrates with differing crystal structures.

The optical properties of 100 and 111 textured wafers are shown in FIGS. 2.4 and 2.5. Complete broadband antireflection is demonstrated for substrates that were coated with 100 nm and 200 nm coatings. FIG. 2.6 shows a 4 inch wafer that has been textured using this process.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. In an embodiment, the term “about” can include traditional rounding according to significant figures of the numerical value. In addition, the phrase “about ‘x’ to ‘y’” includes “about ‘x’ to about ‘y’”.

While only a few embodiments of the present disclosure have been shown and described herein, it will become apparent to those skilled in the art that various modifications and changes can be made in the present disclosure without departing from the spirit and scope of the present disclosure. All such modification and changes coming within the scope of the appended claims are intended to be carried out thereby.

We claim at least the following:

1. A method of forming an antireflective layer on a substrate, comprising:
disposing a multi-cyrstalline silicon substrate in a solution;
disposing the particles in the solution so that the particles cover the surface of the solution, wherein the particles are silica particles having a diameter of about 500 nm or less;
removing the substrate from the solution so that the particles form a colloidal monolayer of particles on the surface of the substrate;
etching the substrate having the colloidal monolayer of particles disposed thereon to form the an antireflective layer on the substrate, wherein the antireflective layer has a height of about 500 nm to 1000 nm, wherein the antireflective layer has a plurality of pillars that have a spacing of about 10 nm to 300 nm between a pair of pillars as measured from pillar base to pillar base, and the pillar has a diameter at the base of about 50 to 300 nm; and
removing the colloidal monolayer of particles.

2. A structure comprising:
a multi-crystalline silicon substrate having an antireflective layer that has a total specular reflection of less than 10%, wherein the antireflective layer has a height of about 500 nm to 1000 nm, wherein the antireflective layer has a plurality of pillars that have a spacing of about 10 nm to 300 nm between a pair of pillars as measured from pillar base to pillar base, and wherein the pillar has a diameter at the base of about 50 to 300 nm.

3. A method of forming an antireflective layer on a substrate, comprising:
forming a colloidal monolayer of particles on a surface of a substrate; and
etching the substrate having the colloidal monolayer of particles disposed thereon to form the an antireflective layer on the substrate.

4. The method of claim 3, wherein the substrate is selected from the group consisting of: a silicon substrate, a gallium arsenide (GaAs) substrate, a gallium antimonide (GaSb) substrate, indium phosphide (InP), and gallium nitride (GaN).

5. The method of claim 4, wherein the silicon substrate is a multi-cyrstalline silicon substrate.

6. The method of claim 4, wherein the particles are silica particles having a diameter of about 500 nm or less.

7. The method of claim 6, wherein the silica particle has a diameter is about 100 to 300 nm.

8. The method of claim 3, wherein forming includes:
disposing the substrate in a solution;
disposing the particles in the solution so that the particles cover the surface of the solution; and
removing the substrate from the solution so that the particles form the colloidal monolayer of particles on the surface of the substrate.

9. The method of claim 8, wherein the solution is water and the particles are disposed in ethylene glycol prior to being disposed in the solution.

10. The method of claim 3, wherein the etching is reactive ion etching.

11. The method of claim 3, further comprising:
removing the colloidal monolayer of particles.

12. The method of claim 3, wherein the antireflective layer has a height of about 500 nm to 1000 nm.

13. The method of claim 3, wherein the antireflective layer has a plurality of pillars that have a spacing of about 10 nm to 300 nm between a pair of pillars as measured from pillar base to pillar base, and the pillar has a diameter at the base of about 50 to 300 nm.

14. The method of claim 3, wherein the antireflective layer has a height of about 500 nm to 1000 nm, wherein the antireflective layer has a plurality of pillars that have a spacing of about 10 nm to 300 nm between a pair of pillars as measured from pillar base to pillar base, and the pillar has a diameter at the base of about 50 to 300 nm.

15. A structure comprising:
a multi-crystalline silicon substrate having an antireflective layer that has a total specular reflection of less than 10%.

16. The structure of claim 15, wherein the antireflective layer has a height of about 500 nm to 1000 nm.

17. The structure of claim 16, wherein the antireflective layer has a plurality of pillars that have a spacing of about 10 nm to 300 nm between a pair of pillars as measured from pillar base to pillar base, and the pillar has a diameter at the base of about 50 to 300 nm.

18. The structure of claim 15, wherein the antireflective layer has a total specular reflection of less than 5%.
